(19) United States
(12) Patent Application Publication
(10) Pub. No.: US 2002/0192930 A1
(43) Pub. Date: Dec. 19, 2002

(54) Method of forming a single crystalline silicon pattern utilizing a structural selective epitaxial growth technique and a selective silicon etching technique

(76) Inventors: Hwa-Sung Rhee, Seoul (KR); Nae-In Lee, Seoul (KR); Tae-Hee Choe, Seoul (KR); Sang-Su Kim, Yongin-shi (KR); Geum-Jong Bae, Suwon (KR)

Correspondence Address: The Law Offices of Eugene M Lee, PLLC, 1101 Wilson Boulevard, Suite 2000, Arlington, VA, 22209, US

(21) Appl. No.: 09/985,616

(22) Filed: Nov. 5, 2001

(30) Foreign Application Priority Data
Jun. 2, 2001 (KR) 2001-31031

(51) Int. Cl. H01L 21/20

(52) U.S. Cl. 438/504

(57) ABSTRACT

A method of forming a single crystalline silicon pattern using a structural selective epitaxial growth technique and a selective silicon etching technique, wherein an insulating layer pattern is formed on a semiconductor substrate; polycrystalline silicon is grown on the insulating layer pattern and simultaneously, single crystalline silicon is grown on the semiconductor substrate between the insulating layer patterns. Then, the polycrystalline silicon is removed from the insulating layer pattern. Preferably, the growing of the silicon is performed at a temperature of between about 700 to about 750° C. and a pressure of between about 5 to about 200 Torr. Removing the polycrystalline silicon is performed at a temperature of between about 700 to about 800° C. employing an etch recipe in which polycrystalline silicon has a faster etching rate than single crystalline silicon.

### BACKGROUND OF THE INVENTION

1. Field of the Invention

The present invention relates to a method of fabricating a semiconductor device. More particularly, the present invention relates to a method of forming a single crystalline silicon pattern using a structural selective epitaxial growth technique and a selective silicon etching technique.

2. Description of the Related Art

During fabrication of a semiconductor device, a selective epitaxial growth technique of single crystalline silicon is employed to facilitate fabrication of semiconductor devices having various structures. In a conventional technique, such as a method of forming a single crystalline silicon pattern through epitaxial growth, there is a conventional selective epitaxial growth (SEG) method, or a method of solid phase epitaxy (SPE), and selective vapor phase etching as suggested by Miyano et al. (“Miyano's method”). Miyano's method was published in a paper published in the Technical Digest of International Electron Devices Meeting (IEDM, pp. 433-36, 2000), entitled: “Low Thermal Budget Elevated Source/Drain Technology Utilizing Novel Solid Phase Epitaxy and Selective Vapor Phase Etching.”

FIG. 1 illustrates a flow chart explaining a method of forming a single crystalline silicon pattern using a conventional selective epitaxial growth (SEG) method.

Referring to FIG. 1, a semiconductor substrate having a surface that is partially covered by an insulating layer pattern is prepared (10). A hydrogen (H₂) annealing process (20) is performed with respect to the semiconductor substrate including the insulating layer pattern. The hydrogen annealing process is performed at a high temperature of approximately 850° C. in order to remove a natural oxide layer formed on the exposed semiconductor substrate. Next, a single crystalline silicon layer is grown (30) using a chemical vapor deposition (CVD) technique, at the semiconductor substrate where the annealing process (20) is completed.

The CVD technique is classified by two methods, low-pressure chemical vapor deposition (LPCVD) and ultra high vacuum chemical vapor deposition (UHVCVD). In order to selectively grow the single crystalline silicon only on the exposed semiconductor substrate, however, the LPCVD method should be performed at a high temperature of approximately 850° C. Although, in the case of forming elevated source/drain regions using the LPCVD method, it is difficult to form a shallow junction since impurities included at the source/drain junctions are diffused because of the high temperature of approximately 850° C. In addition, the selective single crystalline silicon growth by the UHVCVD method has a slow growth rate of the single crystalline silicon despite being performed at a low temperature, less than approximately 700° C. Thus, the UHVCVD method has a problem in that the efficiency is decreased during fabrication of a semiconductor device.

FIG. 2 illustrates a flow chart explaining a method of forming a single crystalline silicon pattern according to Miyano's method.

Referring to FIG. 2, a semiconductor substrate having a surface that is partially covered by an insulating layer pattern is prepared (40). Amorphous silicon is conformally formed (50) over the entire surface of the semiconductor substrate including the insulating layer pattern. Next, the SPE process (60) is performed. Here, the SPE process thermally treats the semiconductor substrate where the amorphous silicon is formed, at the temperature of 600° C. for 3 hours. Thus, the amorphous silicon becomes a polycrystalline silicon layer at the surface of the insulating layer pattern, and becomes a single crystalline silicon layer at the semiconductor substrate. The selective vapor phase etching process (70) is performed at a temperature of 740° C. with respect to the resultant structure on which the SPE process is completed. The selective vapor phase etching process is performed employing an etching recipe in which the polycrystalline silicon has a faster etching rate than the single crystalline silicon. As a result, the polycrystalline silicon layer is removed and only the single crystalline silicon pattern remains.

Although Miyano's method is performed at a low temperature as a method of forming a single crystalline silicon pattern, the method has a problem in that too much time is spent in the SPE step (60) including the thermal treatment process.

### SUMMARY OF THE INVENTION

Therefore, it is a feature of an embodiment of the present invention to provide a method that can effectively form a single crystalline silicon pattern through a low temperature process.

This feature may be provided by a method of forming a single crystalline silicon pattern according to an embodiment of the present invention. The method employs a structural selective epitaxial growth technique and a selective silicon etching technique. The method includes the following steps. Initially, an insulating layer pattern is formed on a semiconductor substrate. Then, a polycrystalline silicon layer is grown on the insulating layer pattern; simultaneously, a single crystalline silicon layer is grown on the semiconductor substrate between the insulating layer patterns. Next, the polycrystalline silicon layer on the insulating layer pattern is removed.

The growing of the silicon is preferably performed at a temperature of between about 700 to about 750° C. and a pressure of between about 5 to about 200 Torr using a mixture gas of a silicon source gas and a carrier gas. The silicon source gas is at least one selected from the group consisting of silane (SiH₄), silicon tetrachloride (SiCl₄), silane dichloride (SiH₂Cl₂), and silane trichloride (SiHCl₃). The carrier gas is at least one selected from the group consisting of hydrogen (H₂), nitrogen (N₂) and argon (Ar).

Additionally, the removing of the polycrystalline silicon is preferably performed at a temperature of between about 700 to about 800° C. using a mixture gas of hydrochloric acid (HCl) gas and hydrogen (H₂). Also, the removing of the polycrystalline silicon layer is preferably performed by employing the etching recipe in which the polycrystalline silicon has a faster etching rate than the single crystalline silicon.

These and other features of the present invention will be readily apparent to those of ordinary skill in the art upon review of the detailed description that follows.

### BRIEF DESCRIPTION OF THE DRAWINGS

FIGS. 1 and 2 illustrate flow charts explaining a method of forming a single crystalline silicon pattern according to conventional techniques.

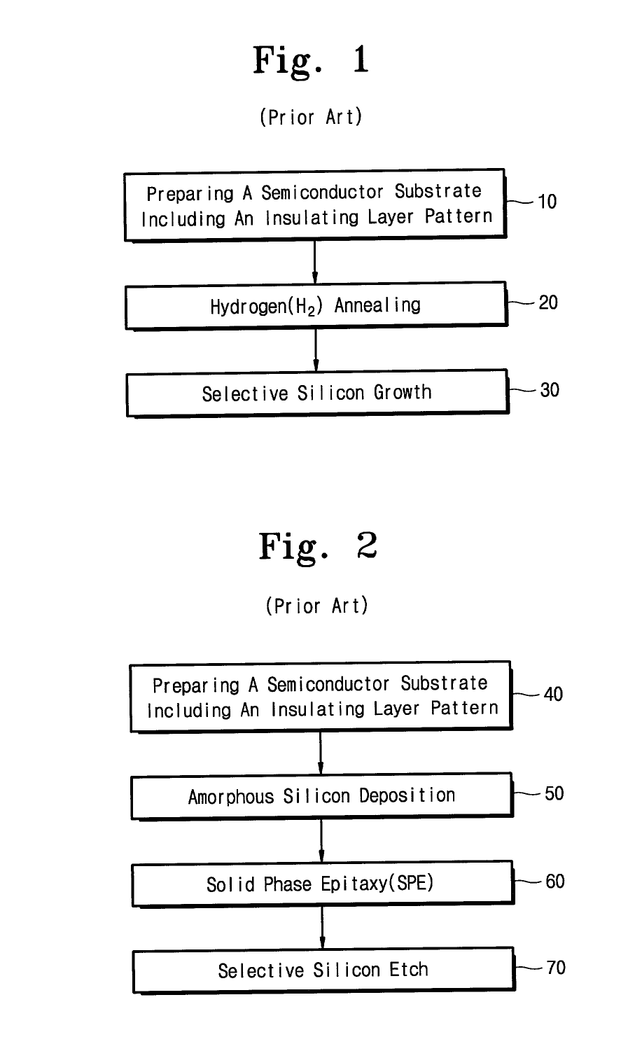

FIG. 3 illustrates a flow chart explaining a method of forming a single crystalline silicon pattern according to a preferred embodiment of the present invention.

FIGS. 4 through 6 illustrate cross-sectional views of a method of forming a single crystalline silicon pattern according to a preferred embodiment of the present invention.

FIGS. 7 and 8 illustrate cross-sectional views of a method of forming a single crystalline silicon pattern according to another preferred embodiment of the present invention.

### DETAILED DESCRIPTION OF THE PREFERRED EMBODIMENTS

Korean Patent Application No. 2001-31031, filed on Jun. 2, 2001, and entitled: “Method of Forming Single Crystalline Silicon Pattern Utilizing Structural Selective Epitaxial Growth Technique and Selective Silicon Etching Technique,” is incorporated by reference herein in its entirety.

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those of ordinary skill in the art. Moreover, when it is mentioned that a layer is on another layer or on a substrate, the layer may be directly formed on another layer or on a substrate, or a third layer may be interposed therebetween.

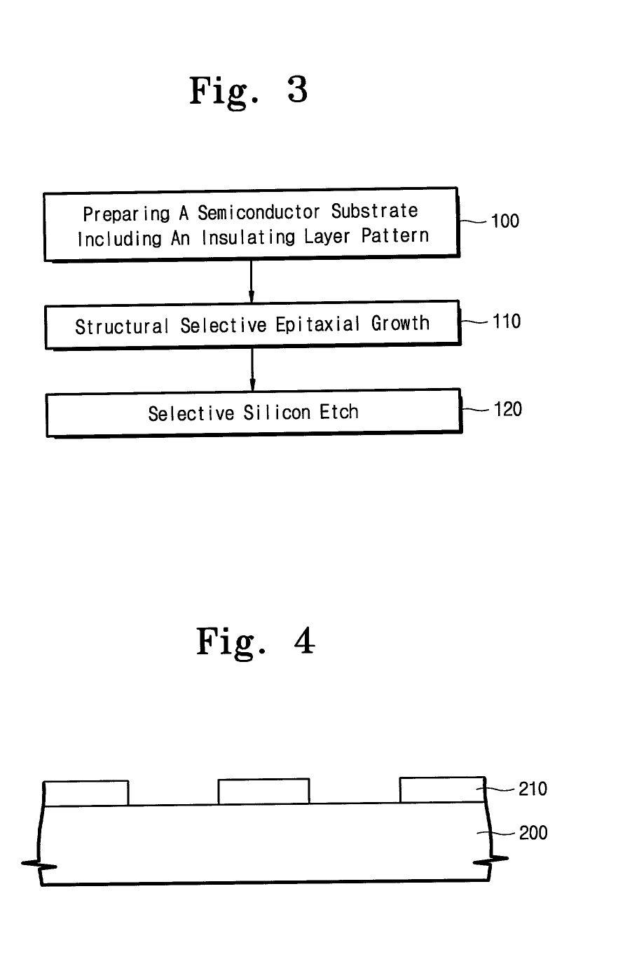

FIG. 3 illustrates a flow chart explaining a method of forming a single crystalline silicon pattern using a structural selective epitaxial growth technique and a selective silicon etching technique according to a preferred embodiment of the present invention.

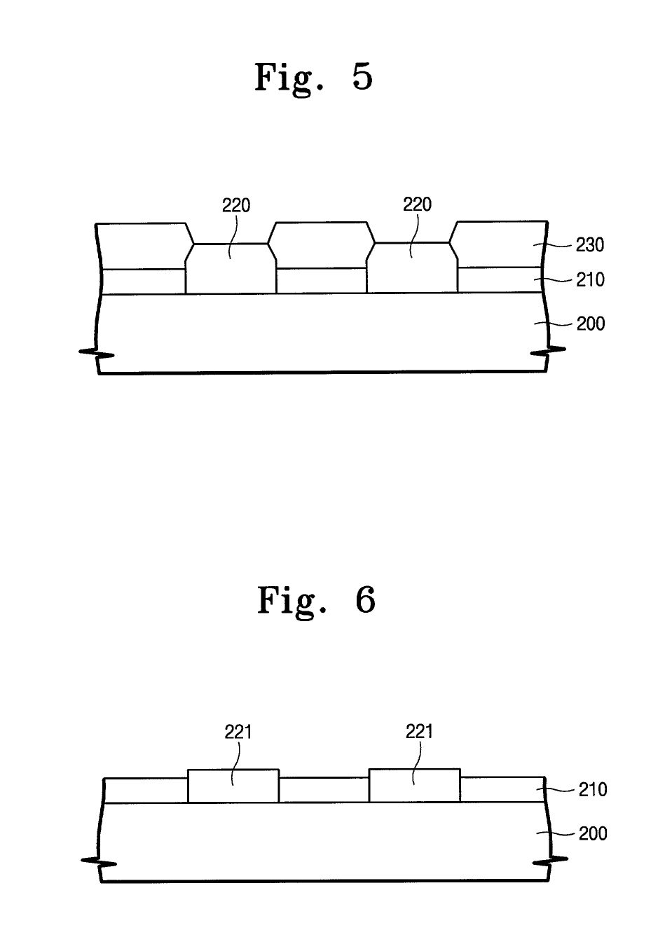

Also, FIGS. 4 through 6 illustrate cross-sectional views of a method of forming a single crystalline silicon pattern using a structural selective epitaxial growth technique and a selective silicon etching technique according to a preferred embodiment of the present invention.

Referring to step (100) of FIG. 3 and to FIG. 4, after forming an insulating layer over the entire surface of a semiconductor substrate 200, the insulating layer is patterned until a top surface of a desired region of the semiconductor substrate is exposed to form an insulating layer pattern 210.

Referring to step (110) of FIG. 3 and to FIG. 5, a structural selective epitaxial growth process (110) is performed with respect to the semiconductor substrate including the insulating layer pattern 210. The structural selective epitaxial growth process (110) is a technique of selectively determining the crystalline structure of silicon according to the property of a bottom material layer. That is, the structural selective epitaxial growth process (110) is a technique of growing single crystalline silicon when the bottom material layer is composed of the single crystalline silicon, and growing a polycrystalline silicon when the bottom material layer is composed of the insulating layer.

As illustrated in FIG. 5, a single crystalline silicon layer 220 is grown at the top surface of the exposed semiconductor substrate and a polycrystalline silicon layer 230 is grown at the surface of the insulating layer pattern 210 by the structural selective epitaxial growth process (110).

The structural selective epitaxial growth process (110) is a CVD method using a mixture gas of a silicon source gas and a carrier gas at a process temperature of between about 700 to about 750° C. and a process pressure of between about 5 to about 200 Torr. The silicon source gas is at least one selected from the group consisting of silane (SiH₄), silicon tetrachloride (SiCl₄), silane dichloride (SiH₂Cl₂) and silane trichloride (SiHCl₃). Also, the carrier gas is at least one selected from group consisting of hydrogen (H₂), nitrogen (N₂) and argon (Ar). The silicon source gas and the carrier gas are preferably silane gas and hydrogen, respectively.

Table 1 represents actual experimental conditions and results using the structural selective epitaxial growth technique (110).

TABLE 1

| Temperature | 750° C. | |
|---|---|---|
| Pressure | 20 Torr | |
| Reacted gas and | Silane (SiH₄) | 200 sccm |
| flowrate | Hydrogen (H₂) | 35,000 sccm |

| | |
|---|---|
| Deposition rate | 735.54 Å/min |

The process temperature of 750° C. is lower than the temperature of single crystalline growth by a conventional LPCVD method, i.e., 850° C. Thus, it is possible to form a relatively shallow junction in comparison to a conventional LPCVD method.

Also, as demonstrated in Table 1, the structural selective epitaxial growth method (110) that can deposit a single crystalline silicon layer at a deposition rate of 735.54 Å/min is more effective than Miyano's method, which includes the SPE process performing thermal treatment for three hours.

Referring to step (120) of FIG. 3 and to FIG. 6, a selective silicon etching process (120) is performed with respect to the resultant structure of the semiconductor substrate where the structural selective epitaxial growth (110) is completed.

The selective vapor etching process (120) is performed at a process temperature of between about 700 to about 800° C. using a mixture gas of hydrochloric acid (HCl) gas and hydrogen (H₂). As a result, the polycrystalline silicon is etched about 5.7 times faster than the single crystalline silicon. This etching rate difference of the selective silicon etching process (120) is caused by the difference of crystallinity of the deposited silicon layer. In order to minimize the impurity diffusion of the junction and at the same time, to effectively perform the process, it is preferable to etch at a process temperature of approximately 740° C. As a result, although the polycrystalline silicon layer 230 is entirely removed, the single crystalline silicon layer 220 is partially recessed to form a single crystalline silicon pattern 221.

The single crystalline silicon pattern 221 between the insulating layer patterns 210 may be used as an active region, and at this time, the insulating layer pattern 210 functions as an isolation layer. The method of forming the isolation layer can replace a conventional method in that a trench is formed at a semiconductor substrate and filled by an insulating layer.

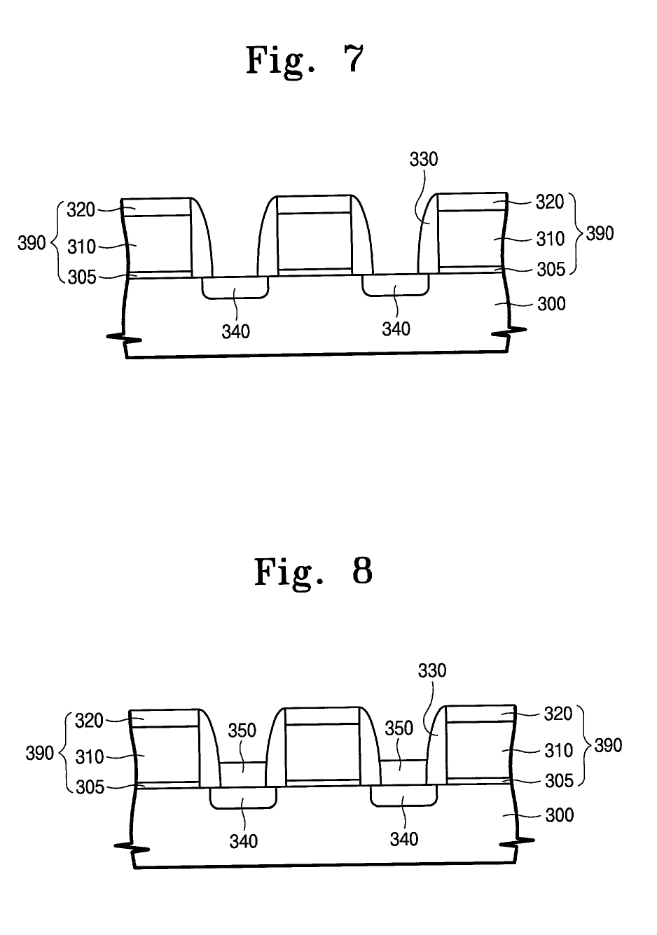

FIGS. 7 and 8 illustrate cross-sectional views of a method of forming an elevated junction according to another preferred embodiment of the present invention.

Referring to FIG. 7, a gate oxide layer pattern 305, a gate electrode 310 and a capping insulating layer pattern 320 are sequentially stacked on a semiconductor substrate 300 to form a gate pattern 390. A spacer 330 is formed at the sidewall of the gate pattern 390. A source/drain ion-implantation process is performed using the spacers 330 and the gate pattern 390 as ion-implantation masks to form source/drain junctions 340 at the semiconductor substrate between the spacers 330.

After forming the gate pattern 390, a low concentration ion-implantation process may be performed in order to form a lightly doped drain (LDD) region, using the gate pattren 390 as an ion-implantation mask.

Referring to FIG. 8, the structural selective epitaxial growth process (110) explained in FIG. 5 is performed with respect to the semiconductor substrate including the source/drain junctions 340.

As a result, a single crystalline silicon layer 350 is grown on the source/drain junctions 340, and a polycrystalline silicon layer (not illustrated here) is grown at the top surfaces of the capping insulating layer pattern 320 and the spacer 330. The selective silicon etching process (120) explained in FIG. 6 is performed with respect to the semiconductor substrate including the single crystalline silicon layer 350, thereby removing the polycrystalline silicon layer. At this time, although the single crystalline silicon layer 350 is recessed, the single crystalline silicon layer 350 remains between the spacers 330 to form an elevated junction.

By using the structural selective epitaxial growth technique (110) and the selective silicon etching technique (120) performed at a low temperature, less than approximately 750° C., the elevated junction is formed to minimize the diffusion of impurities implanted into the source/drain junctions 340. As a result, a shallow junction may be formed. Also, as explained in Table 1, it is possible to effectively form the elevated junction by the deposition rate of a single crystalline silicon layer of 735.54 Å per minute.

According to the present invention, a single crystalline silicon pattern is formed using the structural selective epitaxial growth technique and the selective silicon etching technique. As a result, it is possible to effectively fabricate a semiconductor device that requires a process condition of low temperature.

A preferred embodiment of the present invention has been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a single crystalline silicon pattern comprising:
forming an insulating layer pattern on a semiconductor substrate;
employing a structural selective epitaxial growth process on the semiconductor substrate including the insulating layer pattern to grow single crystalline silicon on the semiconductor substrate between the insulating layer patterns and simultaneously, to grow polycrystalline silicon on the insulating layer pattern; and
removing the polycrystalline silicon on the insulating layer pattern by employing a selective silicon etching process.

2. The method as claimed in claim 1, wherein the structural selective epitaxial growth process is performed at a temperature of between about 700 to about 750° C.

3. The method as claimed in claim 1, wherein the structural selective epitaxial growth process is performed at a pressure of between about 5 to about 200 Torr.

4. The method as claimed in claim 1, wherein the structural selective epitaxial growth process is performed using a mixture gas of a silicon source gas and a carrier gas.

5. The method as claimed in claim 4, wherein the silicon source gas is at least one selected from the group consisting of silane (SiH₄), silicon tetrachloride (SiCl₄), silane dichloride (SiH₂Cl₂) and silane trichloride (SiHCl₃).

6. The method as claimed in claim 4, wherein the carrier gas is at least one selected from the group consisting of hydrogen (H₂), nitrogen (N₂) and argon (Ar).

7. The method as claimed in claim 1, wherein the selective silicon etching process is performed by employing an etch recipe in which polycrystalline silicon has a faster etching rate than single crystalline silicon.

8. The method as claimed in claim 1, wherein the selective silicon etching process is performed at a temperature of between about 700 to about 800° C.

9. The method as claimed in claim 1, wherein the selective silicon etching process is performed at a temperature of approximately 740° C.

10. The method as claimed in claim 1, wherein the selective silicon etching process is performed using a mixture gas of hydrochloric acid (HCl) gas and hydrogen (H₂).

11. The method as claimed in claim 1, wherein the insulating layer pattern is used as an isolation layer and the single crystalline silicon is used as an active region.

12. A method of forming a single crystalline silicon pattern comprising:
sequentially stacking a gate oxide layer pattern, a gate electrode and a capping insulating layer pattern on a desired region of a semiconductor substrate to form a gate pattern;
forming an insulating layer spacer at a sidewall of the gate pattern;
employing a structural selective epitaxial growth process on the entire surface of the semiconductor substrate including the gate pattern and the insulating layer spacer to selectively grow single crystalline silicon on the exposed semiconductor substrate between the insulating layer spacers and simultaneously, to grow polycrystalline silicon on the spacers and the capping insulating layer pattern; and
removing the polycrystalline silicon on the capping insulating layer pattern and the insulating layer spacer employing a selective silicon etching process.

13. The method as claimed in claim 12, wherein the structural selective epitaxial growth process is performed at a temperature of between about 700 to about 750° C.

14. The method as claimed in claim 12, wherein the structural selective epitaxial growth process is performed at a pressure of between about 5 to about 200 Torr.

15. The method as claimed in claim 12, wherein the structural selective epitaxial growth process is performed using a mixture gas of a silicon source gas and a carrier gas.

16. The method as claimed in claim 15, wherein the silicon source gas is at least one selected from the group consisting of silane (SiH₄), silicon tetrachloride (SiCl₄), silane dichloride (SiH₂Cl₂) and silane trichloride (SiHCl₃).

17. The method as claimed in claim 15, wherein the carrier gas is at least one selected from the group consisting of hydrogen (H₂), nitrogen (N₂) and argon (Ar).

18. The method as claimed in claim 12, wherein the selective silicon etching process is performed by employing an etch recipe in which polycrystalline silicon has a faster etching rate than single crystalline silicon.

19. The method as claimed in claim 12, wherein the selective silicon etching process is performed at a temperature of between about 700 to about 800° C.

20. The method as claimed in claim 12, wherein the selective silicon etching process is performed at a temperature of approximately 740° C.

21. The method as claimed in claim 12, wherein the selective silicon etching process is performed using a mixture gas of hydrochloric (HCl) gas and hydrogen (H₂).

22. The method as claimed in claim 12, wherein after forming the insulating layer spacer, the method further comprises implanting impurity-ions into the semiconductor substrate exposed between the gate patterns to form source/drain junctions, wherein the single crystalline silicon is grown on the source/drain junctions.
